(19) United States
(12) Patent Application Publication
(10) Pub. No.: US 2001/0026482 A1
(43) Pub. Date: Oct. 4, 2001

(54) Semiconductor memory device and electrode therefor

(76) Inventor: Junro Sakai, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 09/779,550

(22) Filed: Feb. 9, 2001

Related U.S. Application Data
(63) Continuation of application No. 09/189,806, filed on Nov. 12, 1998.

(30) Foreign Application Priority Data
Apr. 28, 1992 (JP) HEI4-127519
Aug. 9, 1994 (JP) HEI6-220643

(51) Int. Cl. G11C 29/00

(52) U.S. Cl. 365/200

(57) ABSTRACT

A method for forming a textured polysilicon layer that includes forming a layer of doped polysilicon having a textured surface on the surface of a semiconductor substrate includes a second amorphous silicon film to which a low concentration of dopant has been added is deposited on a first amorphous silicon film to which a high concentration of dopant has been added; the first and second amorphous silicon films are then crystallized by annealing, during which step, silicon atoms are allowed to migrate at the surface of the second amorphous silicon film before the crystallization proceeds from the first amorphous silicon film and reaches the surface of the second amorphous silicon film, thereby forming a texture in the surface of the second amorphous film. A substrate processing apparatus for practicing the method includes a process chamber equipped with a pumping system; a gas introduction device for introducing a process gas into the process chamber; and a substrate holder for positioning a semiconductor substrate inside the process chamber; device for depositing a film of amorphous silicon on a surface of the semiconductor substrate by a vapor-phase reaction that involves conferring energy to the process gas introduced into the process chamber; the gas introduction device dopes a silane-based gas with a gaseous phosphorous compound and introduces it into the process chamber, and is configured to allow the doping ratio of gaseous phosphorous compound in the silane-based gas to be selected from a first doping ratio such that the concentration of phosphorous in the deposited amorphous silicon does not exceed 1×10²⁰ atoms per cc.

### CROSS-REFERENCE TO RELATED APPLICATIONS

The present application is a division of U.S. Ser. No. 09/189,806, filed on Nov. 12, 1998. The present application also claims priority of JP9-332408, filed in Japan on Nov. 16, 1997. The subject matter of U.S. Ser. No. 09/189,806 and JP9-332408 is hereby incorporated herein by reference.

### BACKGROUND OF THE APPLICATION

1. Technical Field of the Invention

The present invention relates to a method that may be used for the production of semiconductor devices such as LSIs (large-scale integrated circuits). In particular it relates to a method and apparatus for forming a textured polysilicon layer that is ideally used for the lower electrodes of capacitor parts in DRAM (a temporary read/write memory that requires memory refresh operations) semiconductor memory devices.

2. Description of Related Art

As semiconductor integrated circuit technology progresses year after year, integration density has increased from 4 megabits to 16 megabits, and even to 256 megabits. As this integration density continues to increase, various measures are now being used in device structures, including the field of semiconductor memory devices such as DRAMs. One such measure is the technique of forming a textured polysilicon layer at the surface of a semiconductor substrate.

FIGS. 6(a) through (d) illustrate the steps of a conventional method for forming a textured polysilicon layer at the surface of a semiconductor substrate. The device structures at each step in FIGS. 6(a) through 6(d) are the same as those disclosed in Unexamined Published Japanese Patent Application (JP-A) No. H4-127519.

As stated in the abovementioned publication, the device structures shown in FIGS. 6(a) through 6(d) are produced by the following procedure. First, a silicon oxide layer 900 is formed by thermal oxidation on the surface of an n-type silicon substrate (not illustrated). An amorphous silicon film 910 is deposited thereupon by a silicon molecular beam source (MBE) (FIG. 6(a)). The amorphous silicon film 910 is then converted to polycrystalline silicon by annealing performed thereafter in vacuo without exposing the substrate to the atmosphere (FIGS. 6(b) through (d)).

In such a case, the surface diffusion rate of silicon atoms in a pure amorphous silicon film 910 is much faster than the solid phase deposition rate. Once a crystalline nucleus 911 has formed on the surface of amorphous silicon film 910, the silicon atoms accumulate at this crystalline nucleus and the crystal grows in the shape of a mushroom as represented by reference number 912 in FIG. 6(c). As a result, a polysilicon layer 913 is obtained with a hemispherical texture formed in its surface as shown in FIG. 6(d).

The abovementioned polysilicon layer 913 having a textured surface is ideal for use in the lower electrodes of capacitor parts in semiconductor memory devices. To increase the integration density of semiconductor memory devices, the capacity of this charge-storing capacitor must be increased. Since the effective surface area within a small two-dimensional space can be increased by using the abovementioned textured polysilicon layer 913 for the lower electrode of this capacitor, it is a very effective way of increasing the memory integration density. The abovementioned hemispherical texture is referred to as HSG (hemispherical grain).

When the abovementioned HSG is used for the lower electrode of the capacitor part in a semiconductor memory device, its resistance must be reduced in practice by doping with considerable quantities of dopants such as phosphorous.

When a polysilicon layer that has been doped with dopants is used for the lower electrode of a capacitor, a depletion layer forms at the surface of the lower electrode when the capacitor is charged by applying a positive bias voltage to the lower electrode. Since the formation of a depletion layer changes the permittivity ε and electrode separation d of the capacitor, it changes the overall capacity of the capacitor. Normally, since the increase of d has a large effect, the capacity is reduced and the amount of charge that can be stored in the capacitor decreases.

Due to problems such as this, it is considered necessary to use a material of low resistance for the lower electrode, such as an n-type semiconductor formed by doping silicon with a high concentration of phosphorous. When a SiN/SiO₂ film having a permittivity equivalent to that of a silicon oxide film of 5 to 9 nm thickness is used as the insulating layer, it is considered necessary to dope the lower electrode with a high concentration of phosphorous of at least 2×10²⁰ atoms per cc or thereabouts.

When an attempt is made to form HSG by crystallizing an amorphous silicon film while doping it with such a large concentration of phosphorous, any crystalline nuclei that may have already formed inside the amorphous silicon layer will cause crystallization to proceed from deeper parts of the amorphous silicon film prior to the formation of HSG. As a result, this approach has the drawback that a smooth surface is formed instead of HSG.

In chemical vapor deposition (CVD) apparatus, amorphous silicon films are deposited by vapor-phase decomposition of a silane-based gas such as disilane (SI₂H₆) or monosilane (SiH₄). In such a case, the deposited film of amorphous silicon is doped with phosphorous by doping the silane-based gas with a gaseous phosphorous compound such as phosphine to dope the amorphous silicon film with phosphorous. After that, the semiconductor substrate is subsequently annealed in vacuo without exposing it to the atmosphere, thereby bringing about polycrystallization of the amorphous silicon film and forming a polysilicon layer.

However, the surface of an amorphous silicon film that has been crystallized by annealing has a smooth surface that exhibits none of the texturing shown in FIGS. 6(a) through 6(d). The present inventors assume that when an amorphous silicon film that has been formed by doping with a high concentration of phosphorous is annealed, crystalline nuclei are initially formed deep within the amorphous silicon film and gradually crystallize out toward the surface therefrom.

FIG. 7 confirms the problem in the case of forming an amorphous silicon film doped with phosphorous as mentioned above. Specifically, FIG. 7 shows the appearance under a scanning electron microscope of HSG formed by annealing an amorphous silicon film doped with 4×10²⁰ atoms per cc, or thereabouts, of phosphorous.

As FIG. 7 shows, when an amorphous silicon film that has been doped with a high concentration of phosphorous of about 4×10²⁰ atoms per cc, annealed, a smooth surface is observed in some places. As mentioned above, this is assumed to result from the progression of crystallization from deep within the film.

The appearance of a smooth surface as shown in FIG. 7 prevents an effective increase in surface area by HSG from being obtained, and leads to a capacitor with insufficient charge storage capacity. As a result, the characteristics of semiconductor devices, such as memory circuits, are impaired, and this can lead to defective products. Although the appearance of a smooth surface can be effectively suppressed by reducing the amount of phosphorous doping, reducing the amount of phosphorous doping leads to a capacitor with smaller capacity and smaller charge storage capacity due to the increased depletion layer as mentioned above.

### OBJECTS AND SUMMARY

It is an object of the present invention to provide a method for the formation of a textured polysilicon layer, such as HSG, on the surface of a semiconductor substrate, while doping it with a sufficient quantity of dopant. In this way, it should be possible to obtain capacitor structures with stable characteristics and increased charge storage capacity. Also, by using capacitors having this sort of structure, an aim of the present invention is to provide a semiconductor memory device with increased memory capacity.

To solve the abovementioned problems, the present invention includes a method for forming a textured polysilicon layer, whereby a layer of doped polysilicon having a textured surface is formed on the surface of a semiconductor substrate. The present invention includes a first step wherein amorphous silicon films are produced, and a second step wherein the amorphous silicon films are annealed.

In the first step, a second amorphous silicon film with a low doping density is formed on a first amorphous silicon film with a high doping density. In the second step, the first and second amorphous silicon films formed in the first step are crystallized by annealing. In this second step, silicon atoms are allowed to migrate at the surface of the second amorphous silicon film before the crystallization proceeding from the first amorphous silicon film reaches the surface of the second amorphous silicon film, thereby forming a texture in the surface of this film.

The concentration of phosphorous in the first amorphous silicon film may be at least 1×10²⁰ atoms per cc when this first amorphous silicon film is deposited and the concentration of phosphorous in the second amorphous silicon film is no more than 1×10² atoms per cc when this second amorphous silicon film is deposited.

The first and second amorphous silicon films may be deposited by chemical vapor deposition using a silane-based gas. During this chemical vapor deposition the amorphous silicon films are deposited with the addition of a gaseous phosphorous compound to the silane-based gas. During the deposition of the second amorphous silicon film a smaller proportion of the gaseous phosphorous compound is added to the silane-based gas than when depositing the said first amorphous silicon film.

After the texture has been formed, the polysilicon layer may be subsequently annealed in an atmosphere of a gaseous phosphorous compound without exposing it to the atmosphere. Annealing in an atmosphere of a gaseous phosphorous compound increases the concentration of phosphorous in the polysilicon layer.

After the second step, the polysilicon layer may be annealed after the surface of the polysilicon layer thereby formed has been oxidized. This annealing disperses the dopant inside the polysilicon layer and distributes it uniformly throughout the polysilicon layer.

The present invention also relates to a substrate processing apparatus that forms an amorphous silicon film on the surface of a semiconductor substrate by a plasma-assisted chemical vapor reaction. The substrate processing apparatus has a process chamber equipped with a pumping system. The process chamber has a gas introduction means which introduces a process gas into the process chamber, a means which forms a plasma by conferring energy to the introduced process gas, and a substrate holder for positioning a semiconductor substrate inside the process chamber.

The gas introduction means dopes a silane-based gas with a gaseous phosphorous compound and introduces it into the process chamber. The gas introduction means allows the doping ratio of gaseous phosphorous compound in the silane-based gas to be selected from a first doping ratio such that the concentration of phosphorous in the deposited amorphous silicon does not exceed 1×10²⁰ atoms per cc and a second doping ratio such that the concentration of phosphorous is at least 1×10²⁰ atoms per cc.

The present invention also relates to a semiconductor memory device which has memory cells equipped with a capacitor part that stores an electrical charge to record a signal. The electrode of this capacitor part is configured from a polysilicon layer obtained by depositing a second amorphous silicon film to which a low concentration of dopant has been added on a first amorphous silicon film to which a high concentration of dopant has been added and then annealing them. The polysilicon layer is endowed with a texture made by silicon atoms migrating at the surface of the second amorphous silicon film before the crystallization proceeding from the first amorphous silicon film reaches the surface of the second amorphous silicon film.

The said electrode may be formed with a cylindrical shape. The polysilicon film of this electrode is obtained by annealing a cylindrical laminated structure of amorphous silicon films. The cylindrical laminated structure of amorphous silicon films is formed by covering the inside and outside of the first amorphous silicon film with the second amorphous silicon film.

### BRIEF DESCRIPTION OF THE FIGURES

FIGS. 1(a)-(d) show the steps of the method according to a first embodiment of the invention of the present application.

FIG. 2 is a front view outlining the configuration of a substrate processing apparatus used to implement the method of FIG. 1.

FIG. 3 is a cross-sectional view outlining the structure of a semiconductor memory device relating to an embodiment of the invention of the present application.

FIGS. 4(a)-(g) illustrate the steps in the formation of capacitor part 98 of the semiconductor memory device shown in FIG. 3.

FIGS. 5(1)-(7) illustrate another set of steps in the formation of capacitor part 98 of the semiconductor memory device shown in FIG. 3.

FIGS. 6(a)-(d) show the steps of a conventional method for forming a textured polysilicon film on the surface of a semiconductor substrate.

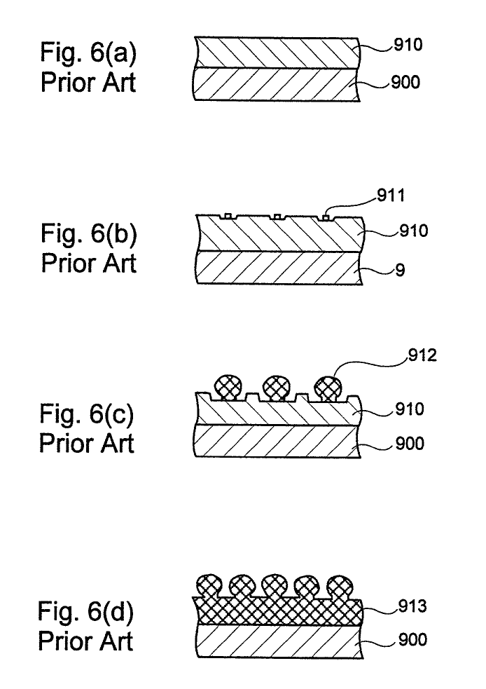

FIG. 7 is a figure confirming the problems that arise when forming a phosphorous-doped amorphous silicon film.

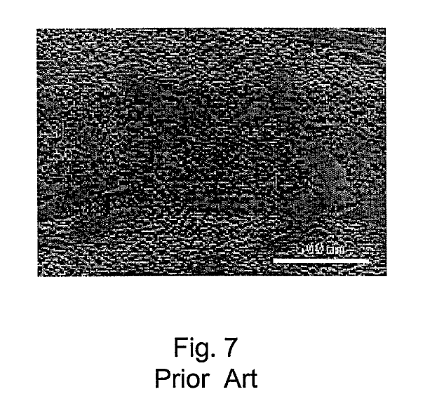

### DETAILED DESCRIPTION OF THE PREFERRED EMBODIMENTS

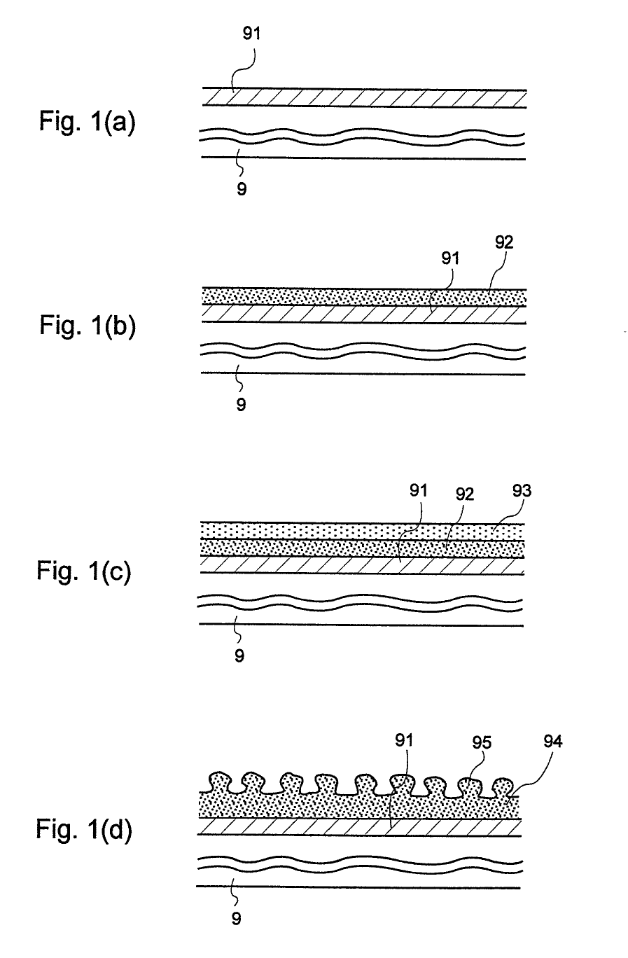

FIGS. 1(a) through 1(d) illustrate each of the steps in the formation of a polysilicon layer 94 having an HSG shape according to a first embodiment of the present invention. In FIG. 1(a), the surface of a silicon semiconductor substrate 9 is subjected to an oxidization process to form a silicon oxide film 91. In FIG. 1(b), an amorphous silicon film with a high concentration of phosphorous (referred to as the “first a-Si film” in the following) 92 is produced by CVD on the silicon oxide film 91. In FIG. 1(c), an amorphous silicon film with a low concentration of phosphorous (referred to as the “second a-Si film” in the following) 93 is produced on the first a-Si film 92. A polysilicon layer 94 having an HSG shape is then formed as shown in FIG. 1(d) by annealing semiconductor substrate 9.

The amorphous silicon layer has a two-layer structure wherein the second a-Si film 93 with a low phosphorous concentration is laminated on top of the first a-Si film 92 with a high phosphorous concentration. When semiconductor substrate 9 is annealed, the crystallization of the amorphous silicon proceeds from deep within the first a-Si film 92, which has a high phosphorous concentration. Meanwhile, at the surface of the second a-Si film, the silicon atoms are relatively free to migrate due to the low phosphorous concentration, so that crystalline nuclei can easily form at the surface. Before the crystallization proceeds from the first a-Si film 92 to the surface of second a-Si film 93, a large number of hemispherical protuberances 95 form at the surface of the second a-Si film 93 as shown in FIG. 1(d). By annealing the semiconductor substrate 9, a polysilicon layer 94 having an HSG shape is obtained. The high concentration of phosphorous inside the first a-Si film 92 diffuses into the second a-Si film 93 either during the abovementioned annealing or during a separate annealing process performed after the HSG formation. As a result, it is possible to obtain a polysilicon layer 94 that is uniformly doped with phosphorous.

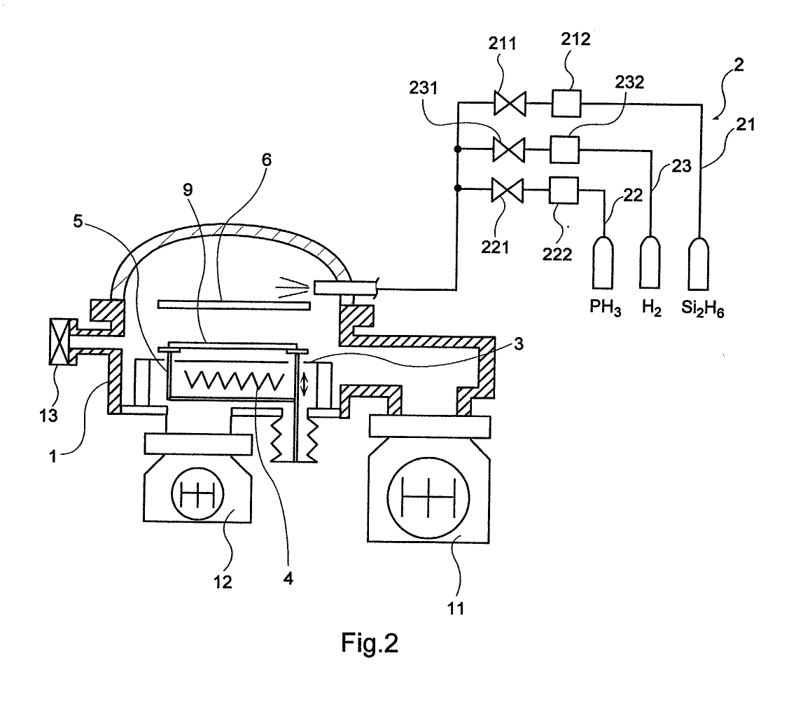

An embodiment of an invention of a substrate processing apparatus used to implement the method of the abovementioned embodiment is described next. FIG. 2 is a front view outlining the configuration of a substrate processing apparatus used to implement the method shown in FIG. 1.

The substrate processing apparatus shown in FIG. 2 has a process chamber 1 equipped with pumping systems 11 and 12, and a gas introduction means 2 which introduces a process gas into process chamber 1. The substrate processing apparatus has a susceptor 3 for positioning a semiconductor substrate 9 inside the process chamber 1, and a heater 4 which heats the semiconductor substrate 9.

The apparatus shown in FIG. 2 is a cold-wall CVD apparatus wherein a cooling mechanism (not illustrated) is fitted to the enclosure walls of the process chamber 1. It is provided with a first pumping system 11 for pumping down the whole of the interior of process chamber 1, and a second pumping system 12 which primarily pumps down the region surrounding heater 4. Pumping systems 11 and 12 both employ ultra-high-vacuum pumping systems using turbo-molecular pumps.

Gas introduction means 2 is equipped with a disilane introduction system 21 which introduces disilane (a silane-based gas), and a phosphine introduction system 22 which introduces phosphine (PH₃; a gaseous phosphorous compound). The disilane introduction system 21 may be equipped with a hydrogen gas introduction system 23, whereby the disilane is mixed with hydrogen as a carrier gas before it is introduced. Each of the systems 21, 22 and 23 is provided with a valve 211, 221 and 231 and a mass-flow controller 212, 222 and 232.

Susceptor 3 is shaped into a block which is fixed to the bottom surface of the process chamber 1, and the semiconductor substrate 9 is mounted on its upper surface. A lift pin 5, which can be raised and lowered, is provided in the interior of the susceptor 3. Lift pin 5 rises and falls through a hole provided in an upper surface of the susceptor 3. When mounting a semiconductor substrate 9 on the susceptor 3, the lift pin 5 is raised up so that it projects from the upper surface of susceptor 3, and the lift pin 5 is lowered after the semiconductor substrate 9 has been mounted on top of the lift pin 5. Semiconductor substrate 9 is thereby mounted on the upper surface of the susceptor 3. Susceptor 3 is formed from a silicon material which contacts semiconductor substrate 9 with good thermal conductivity. The silicon susceptor 3 does not contaminate semiconductor substrate 9 even if this contact is made.

A heater 4 is disposed inside susceptor 3. Heater 4 heats the semiconductor substrate 9 mainly by radiative heating. Heater 4 is a carbon heater which emits heat by conducting electricity. The heat radiated from the heater 4 is conferred to the susceptor 3, and the semiconductor substrate 9 is heated via the susceptor 3. The temperature of semiconductor substrate 9 is sensed by a thermocouple (not illustrated) and is sent to a heater control unit (not illustrated). The heater control unit performs feedback control of the heater 4 according to the sensed result, whereby the temperature of the semiconductor substrate 9 is kept at a set temperature.

To avoid contamination of the atmosphere inside the process chamber 1 by the release of occluded gas from the heater 4, when it becomes hot, the second pumping system 12 pumps down the region surrounding heater 4.

A cooling mechanism (not illustrated) is also provided at the side parts of the susceptor 3. This cooling mechanism prevents the process chamber 1 from being heated by the conduction of heat from the susceptor 3 to the process chamber 1.

A heat-reflecting plate 6 is positioned parallel with the upper side of the semiconductor substrate 9 mounted in the susceptor 3. Heat-reflecting plate 6 reflects the radiation emitted from the semiconductor substrate 9 and the susceptor 3 and returns it to the semiconductor substrate 9, thereby improving the efficiency with which the semiconductor substrate 9 is heated.

Heat-reflecting plate 6 is made of the same material as the film deposited on the surface of the semiconductor substrate 9. This prevents the thin film adhering to the heat-reflecting plate 6 from peeling away. When this film is made of silicon, the heat-reflecting plate 6 is made of silicon.

The silicon film deposited by thermal decomposition of a gaseous silicon hydride compound adheres not only to the surface of the semiconductor substrate 9, but also to the heat-reflecting plate 6. If the heat-reflecting plate 6 is made of a completely different material other than silicon, the thin film will have poor adhesion and can easily peel away due to internal stresses. Parts of the film that peel away will form globular dust particles that float about inside the process chamber 1. If the dust particles adhere to the surface of the semiconductor substrate 9, this will give rise to defects caused by localized reduction of the layer thickness. Such defects are a cause of faults in the resulting semiconductor devices. To prevent the thin film from peeling away, the heat-reflecting plate 6 is made of the same silicon material as the thin film being formed.

The operation of the overall apparatus is controlled by a control unit (not illustrated). The control unit returns signals to each of the mass-flow controllers 212, 222 and 232 of gas introduction means 2, whereby gas is supplied at the desired mass-flow rate and mixing ratio.

The semiconductor substrate 9 with a silicon oxide film 91 formed on its surface as mentioned above is transported into the process chamber 1 via a gate valve 13. Semiconductor substrate 9 is mounted on the susceptor 3 by raising and lowering the lift pin 5. The interior of the process chamber 1 is pumped down in advance to the desired pressure by the first and second pumping systems 11 and 12. Once the semiconductor substrate 9 has been mounted on the susceptor 3, it is heated by the heat from the heater 4 and maintained at the desired temperature after reaching thermal equilibrium.

Gas introduction means 2 introduces a phosphine-doped process gas comprising disilane gas or a gaseous mixture of disilane and hydrogen into process chamber 1. Under the control of pumping speed regulators (not illustrated) provided on the pumping systems 11 and 12, the pressure of process gas inside the process chamber 1 is maintained at the desired pressure. The process gas diffuses inside process chamber 1 and arrives at the surface of the semiconductor substrate 9. The gaseous mixture of silane and hydrogen then decomposes under the heat at the surface of the semiconductor substrate 9, whereby a film of amorphous silicon is deposited at the surface. Here, the control unit causes gas introduction means 2 to dope the process gas with a suitably high ratio of phosphine gas. As shown in FIG. 1(b), a first a-Si film 92 with a high phosphorous concentration is deposited on the silicon oxide film 91.

Next, the control unit sends a signal to the flow regulator 222 of the phosphine gas introduction system 22, whereby the mixing ratio of phosphine gas is reduced. The process gas is introduced into process chamber 1 in this mixing ratio, and the deposition of an amorphous silicon film is continued. As a result, as shown in FIG. 1(c), a second a-Si film 93 with a low phosphorous concentration is deposited on top of the first a-Si film 92.

After the supply of process gas has been halted by stopping the operation of the gas introduction means 2, the annealing step is performed. The annealing step involves leaving the supply of process gas as it is while the semiconductor substrate 9 continues to be heated by the heater 4 inside the susceptor 3. As a result, a polysilicon layer 94 having an HSG shape is obtained as shown in FIG. 1(d).

The abovementioned process chamber 1 ideally has a modular form for use as a multi-chamber apparatus. A multi-chamber apparatus is provided with a central separation chamber and a plurality of process chambers provided around the separation chamber. One of the plurality of process chambers is assigned for use as the process chamber 1 shown in FIG. 2, and other process chambers are designated for use as an annealing chamber and an oxidizing chamber. While a semiconductor substrate 9 on which a polysilicon layer 94 has been formed is being transported in vacuo to the annealing chamber and annealed, this sort of multi-chamber apparatus allows an amorphous silicon film to be deposited on another semiconductor substrate 9. A multi-chamber apparatus thus improves the productivity of semiconductor devices.

An embodiment of a semiconductor memory device having a polysilicon layer 94 is described next.

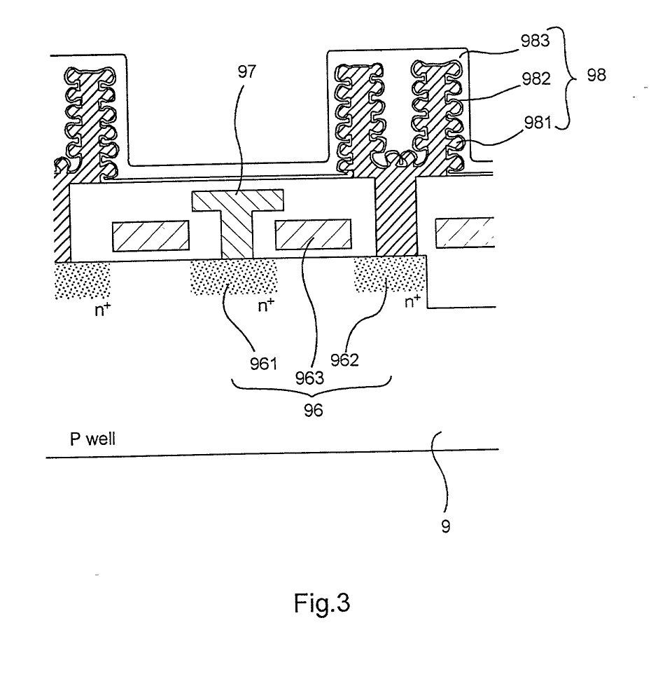

FIG. 3 is a cross-sectional view outlining the structure of a semiconductor memory device relating to an embodiment of the invention of the present application. The semiconductor memory device relating to the present embodiment is a memory cell of a 256 megabit DRAM.

The memory cell in the device of the present embodiment has a MOS-FET part 96 comprising a pair of n-type channels 961 and 962, formed by injecting As into a p-type silicon semiconductor, and a gate electrode 963 connected to a word line (not illustrated). One channel (e.g., the drain) 961 of MOS-FET part 96 is connected to a bit lead 97. A capacitor part 98 is connected to the other channel (e.g., the source) 962 of MOS-FET part 96.

The device of this embodiment operates in the same way as an ordinary DRAM. When a write voltage is applied to the word line of a specific memory cell in the memory array, a signal is input from the bit line. A charge is then stored in the capacitor of capacitor part 98, thereby storing this input signal. When a read voltage is applied to a specific word line, the charge stored in capacitor part 98 is applied to the other channel 962 of MOS-FET part 96, and the stored signal is read out.

In a device according to the abovementioned embodiment, capacitor part 98 may be a polysilicon layer produced by the abovementioned method. Capacitor part 98 has a lower electrode 981, which is the textured polysilicon layer, an insulating layer 982 made of SiN/SiO, which has high permittivity, and a polysilicon upper electrode 983, which is laminated on top of the insulating layer 982.

Alternatively, if the insulating layer 982 is made of Ta₂O₃, the upper electrode 983 should be made of TiN.

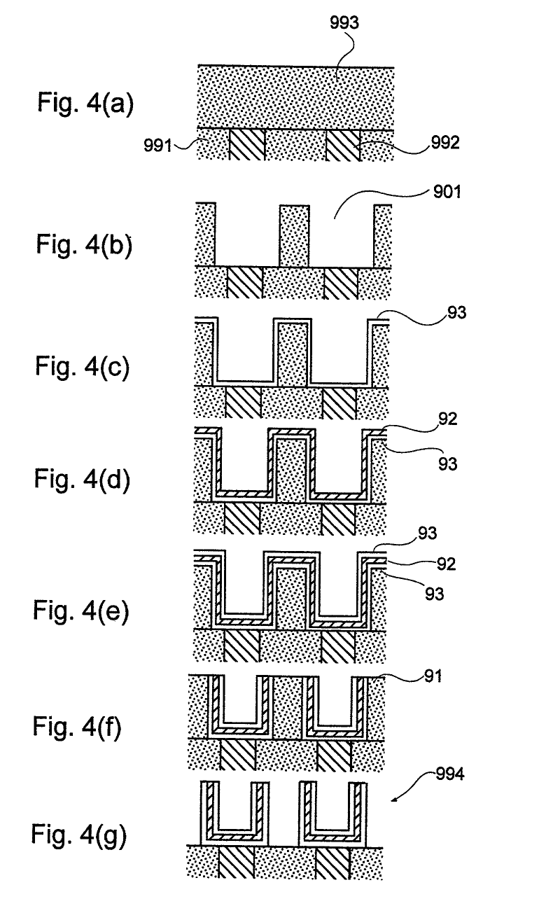

FIGS. 4(a) through 4(g) are sketches showing the steps in the formation of the capacitor part 98 of the semiconductor memory device shown in FIG. 3.

A contact hole is formed by etching a silicon oxide film 991. Polysilicon is embedded into this contact hole to form a contact lead 992. Contact lead 992 is connected to the other channel 962 of the MOS-FET part 96. The semiconductor substrate 9 with contact lead 992 is then subjected to the deposition of a further silicon oxide film 993 (FIG. 4(a)). Next, the silicon oxide film 993 is etched in alignment with the position of the contact lead 992 to form a circular hole 901 (FIG. (b)).

In the semiconductor processing apparatus of the abovementioned embodiment, a second a-Si film 93 is first deposited with a reduced quantity of gaseous phosphorous compound added. The second a-Si film 93 is doped with phosphorous to a concentration of no more than 1×10²⁰ atoms per cc, or thereabouts, and is built up to a thickness of several tens of nm or so (FIG. 4(c)). The doping concentration of no more than 1×10²⁰ atoms per cc, or thereabouts, includes the case where no phosphorous is added at all. The first a-Si film 92 is deposited by increasing the amount of gaseous phosphorous compound added. The first a-Si film 92 with an increased phosphorous concentration is built up to a thickness of up to 50 nm (FIG. 4(d)). The amount of gaseous phosphorous compound added is reduced again, and the second a-Si film 93 with a low phosphorous concentration of no more than 1×10²⁰ atoms per cc is built up to a thickness of several tens of nm (FIG. 4(e)). The configuration of the present embodiment includes the case where the first a-Si film 92 has a phosphorous concentration higher than 1×10²⁰ atoms per cc and the second a-Si film 93 has a phosphorous concentration less than or equal to 1×10²⁰ atoms per cc, and the case where the first a-Si film 92 has a phosphorous concentration greater than or equal to 1×10²⁰ atoms per cc and the second a-Si film 93 has a phosphorous concentration of less than 1×10²⁰ atoms per cc.

Semiconductor substrate 9 is withdrawn from the process chamber, and the first and second a-Si films 92 and 93 are removed from its upper side at the opening of hole 901 by etching or chemical mechanical polishing (CMP) (FIG. 4(f)). Silicon oxide film 991 is removed by Si/SiO₂ selective etching, whereupon a cylindrical amorphous silicon laminated structure 994 is obtained in which the inner and outer surfaces of a first a-Si film 92, which has a high phosphorous concentration, are covered by a second a-Si film 93, which has a low phosphorous concentration (FIG. 4(g)).

The semiconductor substrate 9 is then annealed, whereby cylindrical amorphous silicon laminated structure 994 becomes a polysilicon layer 981 having an HSG shape (FIG. 3). After that, an insulating layer 982 is deposited by sputtering or CVD. Another layer of polysilicon is then deposited on top by CVD to form the upper electrode 983.

In this way, the capacitor part 98 is obtained by the steps shown in FIG. 4.

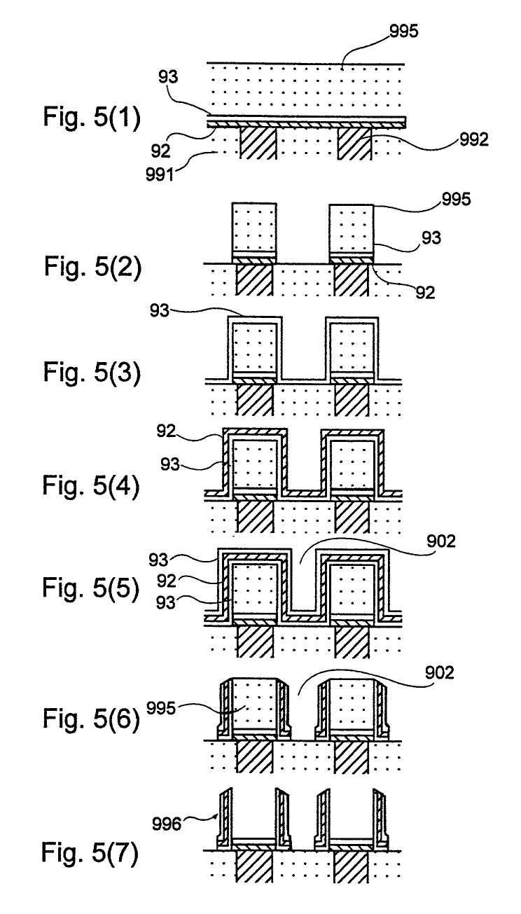

FIG. 5 is a sketch showing another set of steps for the formation of capacitor part 98 in the semiconductor memory device shown in FIG. 3.

A first a-Si film 92 is deposited on a semiconductor substrate 9 having contact leads 992. A second a-Si film 93 is deposited thereupon with the phosphorous concentration reduced to 1×10²⁰ atoms per cc. A silicon oxide film 995 is then deposited on top of the second a-Si film 93 (FIG. 5(1)).

The silicon oxide film 995 and the first and second a-Si films 92 and 93 are then subjected to photo-etching, whereby the silicon oxide film 995 is formed into a cylinder. A cylinder is thereby formed in which the first and second a-Si films 92 and 93 are laminated together at the lower surface of the silicon oxide film 995 (FIG. 5(2)). A second a-Si film 93 with a low phosphorous concentration of 1×10²⁰ atoms per cc, or thereabouts, is then formed to a thickness of several tens of nm at the surface of this semiconductor substrate 9 (FIG. 5(3)). Next, a first a-Si film 92 with a high phosphorous concentration is produced up to a thickness of 50 nm (FIG. 5(4)). Another second a-Si film 93 with a low phosphorous concentration of 1×10²⁰ atoms per cc, or thereabouts, is then formed thereupon with a thickness of several tens of nm (FIG. 5(5)).

The first and second a-Si films 92 and 93 at the upper surface of the cylindrical silicon oxide film 996 and the first and second a-Si films 92 and 93 at the bottom surface of hole 902 are etched away (FIG. 5(6)). Here, the etching is performed by causing ions to impinge perpendicularly to the semiconductor substrate 9 by establishing an electric field perpendicular to the semiconductor substrate 9. This etching leaves behind almost all of the first and second a-Si films 92 and 93 at the side surfaces of cylindrical silicon oxide film 995.

The silicon oxide film 995 is removed by Si/SiO₂ selective etching. As a result, an amorphous silicon film laminated structure 996 is obtained in which the inner surface and the outer surface of first a-Si film 92, which has a high phosphorous concentration, are covered with a second a-Si film 93, which has a low phosphorous concentration (FIG. 5(7)). Then, after performing a photo-etching process, the semiconductor substrate 9 is annealed, whereupon a polysilicon layer 94 having the HSG shape shown in FIG. 3 is obtained. In this way, it is possible to configure a capacitor part 98 in the same way as mentioned above.

In producing the abovementioned capacitor part 98, it is also possible to form a polysilicon layer 94 having an HSG shape and then anneal the semiconductor substrate 9 in an atmosphere of a gaseous phosphorous compound without exposing it to the atmosphere. Annealing with a gaseous phosphorous compound in this way increases the phosphorous concentration in the polysilicon layer 94. If the semiconductor substrate is annealed with a gaseous phosphorous compound, the phosphorous concentration in the first a-Si film 92 need not be so high. This form of annealing delays the conditions whereby crystallization proceeds from the first a-Si film 92. This annealing is also able to form HSG adequately before the crystallization reaches the surface of the second a-Si film 93. When phosphine gas is used, for example, the annealing in a gaseous phosphorous compound might be performed at a pressure of 2 Torr with the temperature of semiconductor substrate 9 at 550° C. or so and a processing time of 40 minutes or so.

After the semiconductor substrate 9 on which the abovementioned polysilicon layer 94 has been formed has been exposed to the atmosphere, and an oxide film has been formed on its surface, the semiconductor substrate 9 is further annealed at 750° C. or so for 30 minutes or so, whereby the phosphorous in the high-concentration region inside the polysilicon layer 94 diffuses uniformly into the low-concentration region. As a result, it is possible to obtain a more even distribution of the phosphorous concentration inside polysilicon layer 94.

Although phosphorous was mentioned as an example of a dopant in the description of the abovementioned embodiment, the invention of the present application can also be implemented in the same way when injecting other types of dopant, such as boron or arsenic. The semiconductor substrate is not restricted to silicon, and may also be a compound semiconductor such as gallium arsenide or the like. The shape of the texture is not restricted to HSG, and other shapes may also be possible. Although the polysilicon layer 94 used as the lower electrode of capacitor 98 was cylindrical, it need not be cylindrical in a strict sense, and may also have a prism shape. It is also possible to employ a structure wherein a plurality of cylindrical shapes of differing diameter are arranged concentrically.

As described above, a capacitor having a polysilicon layer with a texture such as HSG has an increased charge storage capacity and more stable capacitor characteristics. Also, a semiconductor memory device having a capacitor with this sort of structure has increased memory capacity.

Although only preferred embodiments are specifically illustrated and described herein, it will be appreciated that many modifications and variations of the present invention are possible in light of the above teachings and within the purview of the appended claims without departing from the spirit and intended scope of the invention.

What is claimed is:

1. A semiconductor memory device, comprising:
memory cells equipped with a capacitor part that stores an electrical charge to record a signal;
an electrode of the capacitor part is configured from a polysilicon layer obtained by depositing a second amorphous silicon film to which a low concentration of dopant has been added on a first amorphous silicon film to which a high concentration of dopant has been added and then annealing them, and is endowed with a texture made by silicon atoms migrating at the surface of the second amorphous silicon film before the crystallization proceeds from the first amorphous silicon film to reach the surface of the second amorphous silicon film.

2. A semiconductor memory device as claimed in claim 1, wherein the electrode is formed with a cylindrical shape, the polysilicon film of the electrode is obtained by annealing a cylindrical laminated structure of amorphous silicon films, and the cylindrical laminated structure of the amorphous silicon films is formed by covering the inside and outside of the first amorphous silicon film with the second amorphous silicon film.

3. A semiconductor memory device, comprising:
memory cells equipped with a capacitor part that stores an electrical charge to record a signal;
an electrode of the capacitor part includes a polysilicon layer comprised of a first amorphous silicon film to which a first concentration of dopant has been added and a second amorphous silicon film to which a second concentration of dopant has been added, and which first and second silicon films have been annealed;
the first concentration being higher than the second concentration;
the layer has a hemispherical grain texture.

4. The semiconductor device of claim 3, wherein the first concentration is greater than 1×10²⁰ atoms per cc.

5. The semiconductor device of claim 3, wherein the second concentration is not greater than 1×10²⁰ atoms per cc.

6. The semiconductor device of claim 4, wherein the second concentration is not greater than 1×10²⁰ atoms per cc.

7. The semiconductor device of claim 3, wherein the first silicon film is up to 50 nm thick.

8. The semiconductor device of claim 3, wherein the hemispherical grain texture is made by silicon atoms migrating at the surface of the second amorphous silicon film before crystallization proceeds from the first amorphous silicon film to reach the surface of the second amorphous silicon film.

9. The semiconductor device of claim 6, wherein the hemispherical grain texture is made by silicon atoms migrating at the surface of the second amorphous silicon film before crystallization proceeds from the first amorphous silicon film to reach the surface of the second amorphous silicon film.

10. The semiconductor device of claim 7, wherein the hemispherical grain texture is made by silicon atoms migrating at the surface of the second amorphous silicon film before crystallization proceeds from the first amorphous silicon film to reach the surface of the second amorphous silicon film.

11. An electrode, comprising:
a polysilicon layer comprised of a first amorphous silicon film to which a first concentration of dopant has been added and a second amorphous silicon film to which a second concentration of dopant has been added, and which first and second silicon films have been annealed;
the first concentration being higher than the second concentration;
the layer has a hemispherical grain texture.

12. The electrode of claim 11, wherein the first concentration is greater than 1×10²⁰ atoms per cc.

13. The electrode of claim 11, wherein the second concentration is not greater than 1×10²⁰ atoms per cc.

14. The electrode of claim 12, wherein the second concentration is not greater than 1×10²⁰ atoms per cc.

15. The electrode of claim 11, wherein the first silicon film is up to 50 nm thick.

16. The electrode of claim 11, wherein the hemispherical grain texture is made by silicon atoms migrating at the surface of the second amorphous silicon film before crystallization proceeds from the first amorphous silicon film to reach the surface of the second amorphous silicon film.
